(19) United States
(12) Patent Application Publication
(10) Pub. No.: US 2024/0153729 A1
(43) Pub. Date: May 9, 2024

(54) CIRCUIT DEVICE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Shinnosuke NAKAGUCHI, Yokkaichi-shi, Mie (JP); Masayuki KATO, Yokkaichi-shi, Mie (JP); Ryosuke MASUDA, Yokkaichi-shi, Mie (JP)

(21) Appl. No.: 18/548,440

(22) PCT Filed: Feb. 21, 2022
(86) PCT No.: PCT/JP2022/006950

§ 371 Date: Aug. 30, 2023

(30) Foreign Application Priority Data
Mar. 9, 2021 (JP) 2021-037554

(51) Int. Cl. H01H 85/165; B60R 16/03; H02G 5/02

(52) U.S. Cl. CPC H01H 85/165; B60R 16/03; H02G 5/02

(57) ABSTRACT

A circuit device for a vehicle is arranged in a power supply path. In the circuit device, a first conductive pattern and a second conductive pattern are arranged on an insulating layer. The first conductive pattern and the second conductive pattern are connected to each other by a fuse (circuit element). A bus bar is arranged on the first conductive pattern. Therefore, when a current flows through a conductor constituted by the bus bar and the first conductive pattern, the amount of heat generated in the conductor is small.

### CROSS-REFERENCE TO RELATED APPLICATIONS

This application is the U.S. national stage of PCT/JP2022/006950 filed on Feb. 21, 2022, which claims priority of Japanese Patent Application No. JP 2021-037554 filed on Mar. 9, 2021, the contents of which are incorporated herein.

### TECHNICAL FIELD

The present disclosure relates to a circuit device.

### BACKGROUND

JP 2019-33093A discloses a circuit device arranged in a current path. This circuit device includes two conductors that are arranged on an insulating substrate. The two conductors are connected by a thermal cutoff element that functions as a circuit element. A current flows through one of the conductors, the thermal cutoff element, and the other conductor in this order. When a current flows through the thermal cutoff element, heat is generated in the thermal cutoff element. When the temperature of the thermal cutoff element reaches a predetermined temperature, the thermal cutoff element melts. As a result, the flow of current through the two conductors stops.

When a current flows through a conductor, heat is generated in the conductor. When the amount of heat generated in the conductor is large, the temperature of a thermal cutoff element is increased by the heat generated in the conductor. In this case, an unplanned amount of heat is applied to the thermal cutoff element, and accordingly, the thermal cutoff element may not melt at an appropriate timing. Also in a case where a circuit element other than a thermal cutoff element is used, if properties of the circuit element change depending on the temperature of the circuit element, the circuit element may not operate properly.

Therefore, an object of the present disclosure is to provide a circuit device that suppresses the amount of heat generated in a conductor when a current flows through the conductor.

### SUMMARY

A circuit device according to an aspect of the present disclosure is a circuit device for a vehicle configured to be arranged in a power supply path and includes: an insulating layer; a first conductive pattern and a second conductive pattern that are arranged on the insulating layer; a circuit element connecting the first conductive pattern and the second conductive pattern to each other; and a bus bar arranged on the first conductive pattern.

### Advantageous Effects

With the present disclosure, when a current flows through a conductor, the amount of heat generated in the conductor is small.

### BRIEF DESCRIPTION OF DRAWINGS

FIG. 1 is a perspective view of a circuit device according to Embodiment 1.

FIG. 2 is a cross-sectional view of a portion of the circuit device taken along the line A-A shown in FIG. 1.

FIG. 3 is a block diagram showing a configuration of a main part of a power supply system.

FIG. 4 is a plan view of the circuit device from which an upper resist has been removed.

FIG. 5 is a cross-sectional view of the circuit device taken along the line B-B shown in FIG. 4.

FIG. 6 is a cross-sectional view of the circuit device taken along the line C-C shown in FIG. 4.

FIG. 7 is a diagram showing an arrangement of bus bars according to Embodiment 2.

FIG. 8 is a diagram showing an arrangement of bus bars according to Embodiment 3.

FIG. 9 is a diagram showing an arrangement of bus bars according to Embodiment 4.

FIG. 10 is a plan view of a circuit device according to Embodiment 5.

### DETAILED DESCRIPTION OF PREFERRED EMBODIMENTS

First, embodiments of the present disclosure will be listed and described. At least portions of the following embodiments may be combined as appropriate.

A circuit device according to an aspect of the present disclosure is a circuit device for a vehicle configured to be arranged in a power supply path, the circuit device including: an insulating layer; a first conductive pattern and a second conductive pattern that are arranged on the insulating layer; a circuit element connecting the first conductive pattern and the second conductive pattern to each other; and a bus bar arranged on the first conductive pattern.

According to this aspect, the bus bar is arranged on the first conductive pattern. Therefore, a current flows not only through the first conductive pattern but also through the bus bar. Therefore, the resistance value of a conductor constituted by the first conductive pattern and the bus bar is a combined resistance value of the first conductive pattern and the bus bar and is small. Accordingly the amount of heat generated in the conductor is small. The circuit element prevents an overcurrent from flowing through the first conductive pattern and the second conductive pattern, for example. The circuit element in this case is a fuse, a PTC (Positive Temperature Coefficient) thermistor, or the like.

In the circuit device according to an aspect of the present disclosure, the circuit element is a fuse.

According to this aspect, the circuit element is a fuse. When a current flows through the first conductive pattern, the fuse, and the second conductive pattern, heat is generated in the fuse. If a current having a current value of at least a current threshold continuously flows through the circuit element, the temperature of the circuit element reaches or exceeds a predetermined temperature. When the temperature of the circuit element has reached or exceeded the predetermined temperature, the circuit element melts. The flow of current through the first conductive pattern and the second conductive pattern reliably stops as a result of the circuit element melting. Therefore, a fuse is preferably used as the element that prevents an overcurrent from flowing therethrough.

In the circuit device according to an aspect of the present disclosure, a current flows through the second conductive pattern, the circuit element, and the first conductive pattern in this order, and a cross-sectional area of the first conductive pattern taken along a perpendicular direction that is perpendicular to a current direction in which a current flows through the first conductive pattern is smaller than a cross-sectional area of the second conductive pattern taken along the perpendicular direction.

According to this aspect, the first conductive pattern has a small cross-sectional area, and therefore, the resistance value of the first conductive pattern is large. However, the bus bar is arranged on the first conductive pattern, and therefore, the resistance value of the conductor constituted by the first conductive pattern and the bus bar is small. Accordingly the amount of heat generated in the conductor is small. When the cross-sectional area of the first conductive pattern is small, a significant effect can be obtained by providing the bus bar.

In the circuit device according to an aspect of the present disclosure, a current flows through the second conductive pattern, the circuit element, and the first conductive pattern in this order, and an axial direction of the bus bar matches a current direction in which a current flows through the first conductive pattern.

According to this aspect, the axial direction of the bus bar matches the current direction. Therefore, when a current flows through the conductor constituted by the first conductive pattern and the bus bar, the length of sections in which the current flows only through the first conductive pattern is short.

The circuit device according to an aspect of the present disclosure includes a plurality of the bus bars, and the plurality of bus bars are lined up along a perpendicular direction that is perpendicular to the current direction.

According to this aspect, the axial direction of the plurality of bus bars matches the current direction. Therefore, the amount of heat generated in a conductor constituted by the first conductive pattern and the plurality of bus bars when a current flows through the conductor is further reduced.

The circuit device according to an aspect of the present disclosure includes a plurality of the bus bars, and the plurality of bus bars are lined up along the current direction.

According to this aspect, the axial direction of the plurality of bus bars matches the current direction. Therefore, the amount of heat generated in a conductor constituted by the first conductive pattern and the plurality of bus bars when a current flows through the conductor is further reduced. The plurality of bus bars are lined up along the current direction. Therefore, the length of sections in which a current flowing through the conductor constituted by the first conductive pattern and the plurality of bus bars flows only through the first conductive pattern is further reduced.

The circuit device according to an aspect of the present disclosure includes a second bus bar that is arranged on the second conductive pattern.

According to this aspect, the second bus bar is arranged on the second conductive pattern. Therefore, a current flows not only through the second conductive pattern but also through the second bus bar. Accordingly, the amount of heat generated in a conductor constituted by the second conductive pattern and the second bus bar when a current flows through the conductor is also small.

The circuit device according to an aspect of the present disclosure includes a plurality of the first conductive patterns and a plurality of the circuit elements, the plurality of circuit elements are connected to the second conductive pattern, and the plurality of circuit elements are connected to the plurality of first conductive patterns, respectively.

According to this aspect, a current that is input to a conductor including the second conductive pattern is divided into a plurality of currents. The plurality of currents are input to the plurality of first conductive patterns via the plurality of circuit elements, respectively. In this case, the current value of the current flowing through the second conductive pattern is large, and therefore, a conductor having a large cross-sectional area is used as the second conductive pattern. On the other hand, the number of first conductive patterns is large, and therefore, conductors having small cross-sectional areas are used as the first conductive patterns. The conductors having small cross-sectional areas have large resistance values. Therefore, a significant effect can be obtained by providing the bus bars.

### DETAILS OF EMBODIMENTS OF PRESENT DISCLOSURE

The following describes specific examples of circuit devices according to embodiments of the present disclosure with reference to the drawings. Note that the present disclosure is not limited to the following examples, but is defined by the claims, and is intended to encompass all modifications within the meanings and scope equivalent to the claims.

### Embodiment 1

### Appearance of Circuit Device

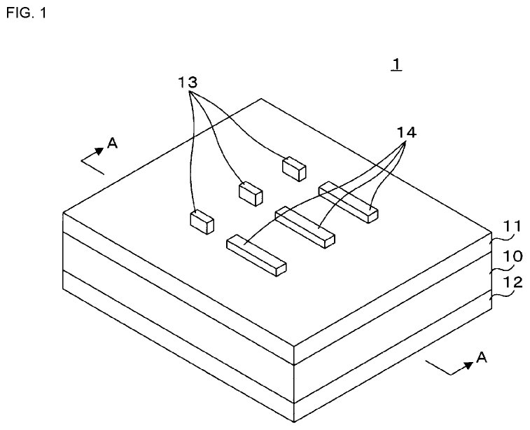

FIG. 1 is a perspective view of a circuit device 1 according to Embodiment 1. In the circuit device 1, an upper surface of an insulating layer 10 that has a rectangular plate shape and insulating properties is covered by an upper resist 11. A lower surface of the insulating layer 10 is covered by a lower resist 12. The upper surface and the lower surface of the insulating layer are main surfaces. Main surfaces of a plate are surfaces that have a large width and are not end surfaces. The upper resist 11 and the lower resist 12 have insulating properties. The upper resist 11 and the lower resist 12 are made of resin, for example.

In the circuit device 1, three fuses 13 and three bus bars 14 are arranged on the upper side of the insulating layer 10. The fuses 13 are blade fuses or chip fuses, for example. The three bus bars 14 are arranged behind the three fuses 13, respectively. The bus bars 14 have rectangular cross sections and extend in the front-rear direction.

Note that the number of fuses 13 and the number of bus bars 14 are not limited to three, and may also be one, two, or four or more. The following describes an example in which the number of fuses 13 and the number of bus bars 14 are both three.

### Cross Section of Circuit Device 1

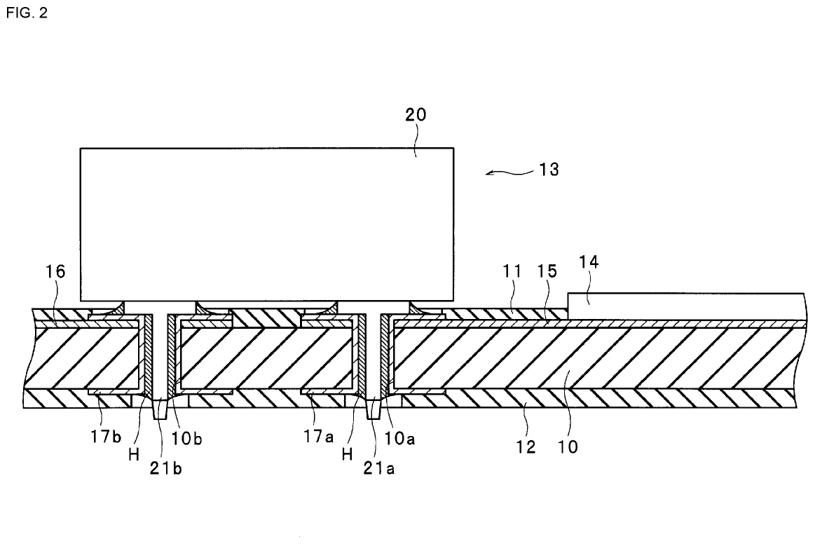

FIG. 2 is a cross-sectional view of a portion of the circuit device 1 taken along the line A-A shown in FIG. 1. In the circuit device 1, a first conductive pattern 15 and a second conductive pattern 16 that have electrical conductivity are arranged on the upper surface of the insulating layer 10. The first conductive pattern 15 is behind the second conductive pattern 16. The insulating layer 10 includes a first through hole 10a and a second through hole 10b extending therethrough in the up-down direction. The first through hole 10a is behind the second through hole 10b.

A portion of the upper surface of the insulating layer 10 around the first through hole 10a is covered by the first conductive pattern 15. An inner surface of the insulating layer 10 inside the first through hole 10a is covered by a first plating 17a, which is electrically conductive. The first plating 17a covers the upper surface of the insulating layer 10 from above the first conductive pattern 15 around the first through hole 10a. The first plating 17a covers the lower surface of the insulating layer 10 from below around the first through hole 10a.

Portions of the first plating 17a covering the upper surface and the lower surface of the insulating layer 10 are continuous to a portion of the first plating 17a covering the inner surface of the insulating layer 10. The first plating 17a is in contact with the first conductive pattern 15. Accordingly the first conductive pattern 15 and the first plating 17a are electrically connected.

Likewise, a portion of the insulating layer 10 around the second through hole 10b is covered by the second conductive pattern 16. An inner surface of the insulating layer 10 inside the second through hole 10b is covered by a second plating 17b, which is electrically conductive. The second plating 17b covers the upper surface of the insulating layer 10 from above the second conductive pattern 16 around the second through hole 10b. The second plating 17b covers the lower surface of the insulating layer 10 from below around the second through hole 10b.

Portions of the second plating 17b covering the upper surface and the lower surface of the insulating layer 10 are continuous to a portion of the second plating 17b covering the inner surface of the insulating layer 10. The second plating 17b is in contact with the second conductive pattern 16. Accordingly, the second conductive pattern 16 and the second plating 17b are electrically connected.

Each fuse 13 includes a fuse main body 20 that has a rectangular parallelepiped shape. A first terminal 21a and a second terminal 21b protrude downward from a lower surface of the fuse main body 20 of the fuse 13. The first terminal 21a and the second terminal 21b are electrically conductive. The first terminal 21a is passed through the first through hole 10a in the insulating layer 10. The first terminal 21a is located on the inner side of the first plating 17a. The first terminal 21a and the first plating 17a are connected by solder H.

Likewise, the second terminal 21b is passed through the second through hole 10b in the insulating layer 10. The second terminal 21b is located on the inner side of the second plating 17b. The second terminal 21b and the second plating 17b are connected by solder H.

The fuse 13 connects the first conductive pattern 15 and the second conductive pattern 16 to each other as described above.

The first terminal 21a and the second terminal 21b are connected to each other by an electrically conductive thermal cutoff portion (not shown) inside the fuse main body 20. A current flows through the second terminal 21b, the thermal cutoff portion, and the first terminal 21a in this order. When a current flows through the thermal cutoff portion, heat is generated in the thermal cutoff portion. If the amount of heat generated in the thermal cutoff portion per unit time exceeds the amount of heat dissipated from the thermal cut off portion per unit time, the temperature of the thermal cutoff portion increases. When the temperature of the thermal cutoff portion included in the fuse 13 has reached or exceeded a predetermined temperature, the thermal cutoff portion melts.

If a current having a current value of at least a current threshold continuously flows through the thermal cutoff portion, the temperature of the thermal cutoff portion reaches or exceeds the predetermined temperature and the thermal cutoff portion melts. When the thermal cutoff portion melts, the flow of current through the first terminal 21a and the second terminal 21b stops. Thus, a situation is avoided in which the current having a current value of at least the current threshold keeps flowing through the first terminal 21a and the second terminal 21b for a long time. The fuse 13 functions as a circuit element.

Each bus bar 14 is arranged on an upper surface of the first conductive pattern 15. The bus bars 14 are in contact with the first conductive pattern 15. Accordingly, the bus bars 14 and the first conductive pattern 15 are electrically connected. The upper resist 11 covers the upper surface of the insulating layer 10 except for portions on which the bus bars 14, the first terminal 21a, and the second terminal 21b are arranged. The upper resist 11 covers the insulating layer 10, the first conductive pattern 15, the second conductive pattern 16, the first plating 17a, and the second plating 17b from above.

Heat generated in the thermal cutoff portion of the fuse 13 is transmitted to the first terminal 21a, the solder H, the first plating 17a, the first conductive pattern 15, and the bus bars 14 in this order. The heat is dissipated from the bus bars 14 to the outside. The heat conductivities of insulating bodies such as the insulating layer 10, the upper resist 11, and the lower resist 12 are commonly lower than the heat conductivities of conductors such as the bus bars 14, the first conductive pattern 15, the second conductive pattern 16, the first plating 17a, the second plating 17b, the first terminal 21a, and the second terminal 21b.

Heat generated in the thermal cutoff portion is efficiently dissipated to the outside because the bus bars 14 are exposed to the outside. Therefore, temperatures of the insulating bodies such as the insulating layer 10, the upper resist 11, and the lower resist 12 are unlikely to increase. Circuit elements other than the fuses 13, such as an integrated circuit element may be arranged on the upper surface or the lower surface of the insulating layer 10. Heat generated in the thermal cutoff portion is efficiently dissipated to the outside, and therefore, the temperature of any circuit elements other than the fuses 13 is unlikely to increase due to the heat generated in the fuses 13. The properties of many circuit elements depend on the temperatures of the circuit elements. However, the temperature of the circuit elements is unlikely to increase, and accordingly, the circuit elements are unlikely to operate improperly due to the heat generated in the thermal cutoff portion.

### Operations of Circuit Device 1

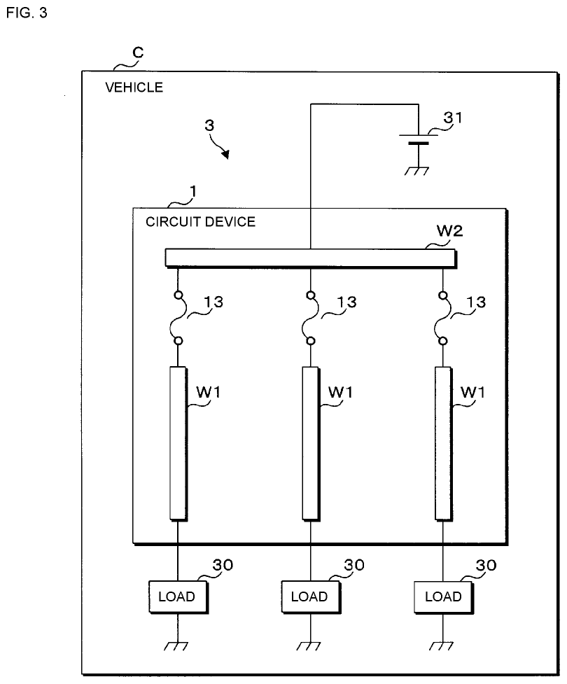

FIG. 3 is a block diagram showing a configuration of a main part of a power supply system 3. The power supply system 3 is installed in a vehicle C. The power supply system 3 includes the circuit device 1, three loads 30, and a DC power source 31. The loads 30 are electric devices. The DC power source 31 is a battery, for example.

In the circuit device 1, first conductors W1 are constituted by the bus bars 14 and the first conductive pattern 15. A second conductor W2 is constituted by the second conductive pattern 16. The circuit device 1 includes three first conductors W1 and the second conductor W2. The three first conductors W1 included in the circuit device 1 are connected to ends on one side of the three loads 30, respectively. The first conductors W1 are connected to the second conductor W2 by the fuses 13. The second conductor W2 is further connected to the positive electrode of the DC power source 31. Ends on the other side of the three loads 30 and the negative electrode of the DC power source 31 are grounded.

A current is input from the positive electrode of the DC power source 31 to the second conductor W2. The current input to the second conductor W2 is divided into three currents. The three currents are output from the second conductor W2 to the fuses 13, respectively. The currents output from the second conductor W2 flow through the fuses 13, the first conductors W1, and the loads 30 in this order. Thus, power is supplied to the loads 30. The loads 30 perform various operations using the power supplied from the DC power source 31.

As described above, the first conductive pattern 15 is included in each first conductor W1, and the second conductive pattern 16 is included in the second conductor W2. Accordingly, a current flows through the second conductive pattern 16, the fuses 13, and the first conductive patterns 15 in this order. The circuit device 1 is arranged in a path for supplying power from the DC power source 31 to the loads 30.

As described above, a current flows through the second terminal 21b, the thermal cutoff portion, and the first terminal 21a in this order in each fuse 13. If a current having a current value of at least the current threshold continuously flows through the thermal cutoff portion, the temperature of the thermal cutoff portion reaches or exceeds the predetermined temperature and the thermal cutoff portion melts. When the thermal cutoff portion of the fuse 13 melts, the flow of current through the second conductor W2 and the first conductor W1 stops. As a result, power supply to the corresponding load 30 stops. When power supply to the load 30 stops, the load 30 stops operating. Thus, a situation is avoided in which the current having a current value of at least the current threshold keeps flowing through the second conductor W2 and the first conductor W1 for a long time.

Note that the number of loads 30 connected to the circuit device 1 is the same as the number of fuses 13. As described above, the number of fuses 13 is not limited to three. Accordingly, the number of loads 30 is not limited to three.

### Arrangement of Bus Bars 14

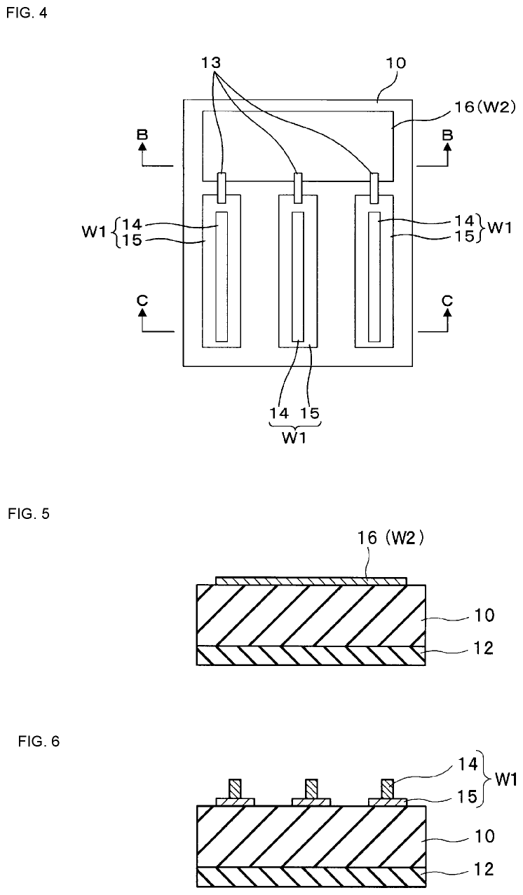

FIG. 4 is a plan view of the circuit device 1 from which the upper resist 11 has been removed. The first conductive patterns 15 and the second conductive pattern 16 each have a rectangular plate shape. As described above, the three first conductive patterns 15 are downstream of the second conductive pattern 16. Each first conductor W1 is constituted by a bus bar 14 and a first conductive pattern 15. The second conductor W2 is constituted by the second conductive pattern 16.

The positive electrode of the DC power source 31 is connected to the second conductive pattern 16 (the second conductor W2). The second terminals 21b of the three fuses 13 are connected to the second conductive pattern 16. The first terminals 21a of the three fuses 13 are connected to the three first conductive patterns 15, respectively. The first terminals 21a of the fuses 13 are located in front end portions of the first conductive patterns 15. Ends on one side of the loads 30 are connected to rear end portions of the first conductive patterns 15. As described above, currents flow through the fuses 13, the first conductors W1, and the loads 30 in this order. Accordingly currents flow from the upstream side to the downstream side in the first conductive patterns 15.

As described above, the bus bars 14 are arranged on the first conductive patterns 15. An axial direction of each bus bar 14 is the front-rear direction and matches a current direction in which a current flows through the corresponding first conductive pattern 15.

Note that it is sufficient that the axial direction of each bus bar 14 substantially matches the current direction. Accordingly, when an angle between the axial direction and the current direction is within the range of design tolerance, the axial direction matches the current direction.

FIG. 5 is a cross-sectional view of the circuit device 1 taken along the line B-B shown in FIG. 4. FIG. 6 is a cross-sectional view of the circuit device 1 taken along the line C-C shown in FIG. 4. FIGS. 5 and 6 show cross sections of the circuit device 1 from which the upper resist 11 has been removed. FIGS. 5 and 6 have the same scale. A perpendicular direction that is perpendicular to the current direction in which a current flows through each first conductive pattern 15 is the left-right direction. FIG. 5 shows a cross section of the second conductive pattern 16 taken along the perpendicular direction. FIG. 6 shows cross sections of the first conductive patterns 15 taken along the perpendicular direction.

The first conductive patterns 15 and the second conductive pattern 16 each have a rectangular cross section. The first conductive patterns 15 and the second conductive pattern 16 have the same height. The width of each first conductive pattern 15 is smaller than the width of the second conductive pattern 16. Accordingly, the area of the cross section of each first conductive pattern 15 taken along the perpendicular direction is smaller than the area of the cross section of the second conductive pattern 16 taken along the perpendicular direction.

Note that it is sufficient that the height of the first conductive patterns 15 and the height of the second conductive pattern 16 are substantially the same. Accordingly, when a difference between the height of the first conductive patterns 15 and the height of the second conductive pattern 16 is within the range of design tolerance, the height of the first conductive patterns 15 is the same as the height of the second conductive pattern 16.

The first conductive patterns 15 and the second conductive pattern 16 each have a resistance component. Therefore, when currents flow through the first conductive patterns 15, heat is generated in the first conductive patterns 15. When a current flows through the second conductive pattern 16, heat is generated in the second conductive pattern 16. The larger the resistance value of a conductor is, the larger the amount of heat generated in the conductor when a current flows through the conductor is. The larger the area of a cross section of a conductor taken along a direction perpendicular to the current direction is, the smaller the resistance value of the conductor is.

The cross section of the second conductive pattern 16 taken along the perpendicular direction has a large area. Accordingly the second conductive pattern 16 (the second conductor W2) has a small resistance value. Therefore, the amount of heat generated in the second conductor W2 is small. The cross section of each first conductive pattern 15 taken along the perpendicular direction has a small area. Accordingly, each first conductive pattern 15 has a large resistance value. However, a bus bar 14 is arranged on each of the first conductive patterns 15. Therefore, a current flows not only through the first conductive pattern 15 but also through the bus bar 14. Accordingly the resistance value of each first conductor W1 constituted by the bus bar 14 and the first conductive pattern 15 is a combined resistance value of the bus bar 14 and the first conductive pattern 15 and is small. Therefore, the amount of heat generated in each first conductor W1 is small. In the case where the cross-sectional area of each first conductive pattern 15 is small, a significant effect can be obtained by providing the bus bar 14.

The larger power consumption by a conductor is, the larger the amount of heat generated in the conductor is. Power consumption by a conductor is expressed as a product of the resistance value of the conductor and the square of a current value of a current flowing through the conductor. Accordingly the larger the resistance value is, the larger the amount of heat generated in the conductor is.

As described above, the axial direction of each bus bar 14 matches the current direction. Therefore, the length of sections in which a current flowing through the first conductor W1 flows only through the first conductive pattern 15 is short. There are two such sections in the example shown in FIG. 4. A first section is a region between the fuse 13 and the bus bar 14. A second section is a region from the rear end of the bus bar 14 to the rear end of the first conductive pattern 15. The shorter the length of sections in which a current flows only through the first conductive pattern 15 is, the smaller the area of regions in which a large amount of heat is generated is.

The number of first conductors W1 is the same as the number of fuses 13. Accordingly, the number of first conductors W1 may be one, or two or more. In a configuration in which currents are input from the second conductive pattern 16 to a plurality of first conductive patterns 15, the current value of a current flowing through the second conductive pattern 16 is large. Therefore, a conductor that has a large cross-sectional area is used as the second conductive pattern 16. On the other hand, the number of first conductive patterns 15 is large. Therefore, conductors that have small cross-sectional areas are used as the first conductive patterns 15. Conductors having small cross-sectional areas have large resistance values. Therefore, a significant effect can be obtained by providing the bus bars 14. If the bus bars 14 are not used, it is necessary to use conductive patterns that have large cross-sectional areas as the first conductive patterns 15. In this case, the number of loads 30 that can be connected to the circuit device 1 is limited.

### Variation of Embodiment 1

When the number of first conductive patterns 15 is two or more, the shape of a first conductive pattern 15 may differ from the shape of another first conductive pattern 15. For example, the length of a first conductive pattern 15 in the left-right direction may differ from the length of another first conductive pattern 15 in the left-right direction. Alternatively, the length of a first conductive pattern 15 in the front-rear direction may differ from the length of another first conductive pattern 15 in the front-rear direction.

### Embodiment 2

In Embodiment 1, one bus bar 14 is arranged on each first conductive pattern 15. However, a configuration is also possible in which two or more bus bars 14 are arranged on a common first conductive pattern 15.

The following describes differences of Embodiment 2 from Embodiment 1. Configurations other than configurations described below are common between Embodiment 2 and Embodiment 1. Therefore, common components are denoted by the same reference signs as those used in Embodiment 1, and descriptions thereof are omitted.

### Arrangement of Bus Bars 14

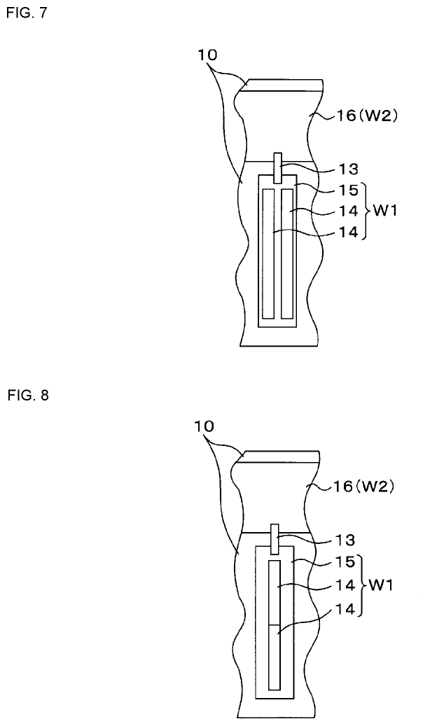

FIG. 7 is a diagram showing an arrangement of bus bars 14 according to Embodiment 2. In a circuit device 1 according to Embodiment 2, two bus bars 14 are arranged on a common first conductive pattern 15. The axial direction of each of the two bus bars 14 matches the current direction in which a current flows through the first conductive pattern 15 as in Embodiment 1. The two bus bars 14 are lined up along the perpendicular direction (the left-right direction) perpendicular to the current direction. In Embodiment 2, a first conductor W1 is constituted by the two bus bars 14 and the first conductive pattern 15. In the example shown in FIG. 7, the two bus bars 14 arranged on the same first conductive pattern 15 are spaced apart from each other.

The axial direction of each of the two bus bars 14 matches the current direction. Therefore, the amount of heat generated in the first conductor W1 when a current flows through the first conductor W1 is further reduced. In a configuration in which a plurality of bus bars 14 are arranged, it is possible to use mass-produced bus bars as the bus bars 14.

The same effects as those obtained with use of the circuit device 1 according to Embodiment 1 can be obtained with use of the circuit device 1 according to Embodiment 2.

### Variation of Embodiment 2

The number of bus bars 14 arranged on the common first conductive pattern 15 is not limited to two. Three or more bus bars 14 may also be lined up next to one another along the perpendicular direction. As the number of bus bars 14 increases, it is possible to use a conductive pattern having a smaller cross-sectional area as the first conductive pattern 15. Also, the two bus bars 14 lined up along the perpendicular direction may be in contact with each other.

### Embodiment 3

In Embodiment 2, the plurality of bus bars 14 are lined up along the perpendicular direction on the common first conductive pattern 15. However, the direction along which the plurality of bus bars 14 are lined up is not limited to the perpendicular direction.

The following describes differences of Embodiment 3 from Embodiment 2. Configurations other than configurations described below are common between Embodiment 3 and Embodiment 2. Therefore, common components are denoted by the same reference signs as those used in Embodiment 2, and descriptions thereof are omitted.

### Arrangement of Bus Bars 14

FIG. 8 is a diagram showing an arrangement of bus bars 14 according to Embodiment 3. In Embodiment 3, two bus bars 14 are placed next to each other on a common first conductive pattern 15. The two bus bars 14 are placed next to each other along the current direction (the front-rear direction) in which a current flows through the first conductive pattern 15. In the example shown in FIG. 8, the two bus bars 14 are in contact with each other.

The axial direction of each of the two bus bars 14 matches the current direction. Therefore, the amount of heat generated in the first conductor W1 when a current flows through the first conductor W1 is small as in Embodiment 2. The two bus bars 14 are lined up along the current direction. Therefore, the length of sections in which a current flowing through the first conductor W1 flows only through the first conductive pattern 15 is further reduced. In a configuration in which a plurality of bus bars 14 are arranged, it is possible to use mass-produced bus bars as the bus bars 14 as described in Embodiment 2.

Other than an effect obtained by lining up the plurality of bus bars 14 along the perpendicular direction, all effects obtained with use of the circuit device 1 according to Embodiment 2, can also be obtained with use of the circuit device 1 according to Embodiment 3.

### Variation of Embodiment 3

The number of bus bars 14 arranged on the common first conductive pattern 15 is not limited to two. Three or more bus bars 14 may also be lined up along the current direction. As the number of bus bars 14 increases, it is possible to use, as the first conductive pattern 15, a conductive pattern that has a smaller cross section along the perpendicular direction. Also, the two bus bars 14 lined up along the current direction may be spaced apart from each other. Furthermore, there is no limitation to a configuration in which the two bus bars 14 lined up along the current direction are arranged along a straight line. The axis of one of the bus bars 14 may extend along a line other than a line extended from the axis of the other bus bar 14.

### Embodiment 4

In Embodiment 2, the plurality of bus bars 14 are lined up next to one another along the perpendicular direction on the common first conductive pattern 15. In the configuration of Embodiment 2, a plurality of bus bars 14 may be further lined up along the current direction on the first conductive pattern 15 as in Embodiment 3.

The following describes differences of Embodiment 4 from Embodiment 2. Configurations other than configurations described below are common between Embodiment 4 and Embodiment 2. Therefore, common components are denoted by the same reference signs as those used in Embodiment 2, and descriptions thereof are omitted.

### Arrangement of Bus Bars 14

FIG. 9 is a diagram showing an arrangement of bus bars 14 according to Embodiment 4. In a circuit device 1 according to Embodiment 4, three bus bars 14 are arranged on a common first conductive pattern 15. Two bus bars 14 out of the three bus bars 14 are lined up along the perpendicular direction as in Embodiment 2. Furthermore, two bus bars 14 out of the three bus bars 14 are lined up along the current direction as in Embodiment 3. In the example shown in FIG. 9, the three bus bars 14 are arranged in a staggered manner on the common first conductive pattern 15.

The same effects as those obtained with use of the circuit devices 1 according to Embodiments 2 and 3 can be obtained with use of the circuit device 1 according to Embodiment 4.

### Variation of Embodiment 4

In Embodiment 4, the number of bus bars 14 arranged on the common first conductive pattern 15 is not limited to three, and may also be four or more. As the number of bus bars 14 increases, it is possible to use, as the first conductive pattern 15, a conductive pattern that has a smaller cross section along the perpendicular direction. The number of bus bars 14 lined up along the perpendicular direction is not limited to two, and may also be three or more. The number of bus bars 14 lined up along the current direction is not limited to two, and may also be three or more. The arrangement of the plurality of bus bars 14 on the common first conductive pattern 15 is not limited to the staggered arrangement, and may also be a lattice arrangement. As in Embodiment 2, the two bus bars 14 lined up along the perpendicular direction may be in contact with each other or spaced apart from each other. As in Embodiment 3, the two bus bars 14 lined up along the current direction may be in contact with each other or spaced apart from each other.

### Variation of Embodiment 1

As described above, the number of bus bars 14 arranged on a common first conductive pattern 15 in Embodiment 1 may be one, or two or more. In the case where the number of first conductors W1 is two or more, the number of bus bars 14 arranged on a first conductive pattern 15 may differ from the number of bus bars 14 arranged on the upper surface of another first conductive pattern 15.

In this case, at least two first conductors W1 out of first conductors W1 according to Embodiments 1 to 4 may be included in the plurality of first conductors W1 included in the circuit device 1. As described above, each first conductor W1 is constituted by at least one bus bar 14 and a first conductive pattern 15.

### Embodiment 5

The second conductor W2 in Embodiment 1 is constituted only by the second conductive pattern 16. However, a conductor other than the second conductive pattern 16 may also be included as an element that constitutes the second conductor W2.

The following describes differences of Embodiment 5 from Embodiment 1. Configurations other than configurations described below are common between Embodiment 5 and Embodiment 1. Therefore, common components are denoted by the same reference signs as those used in Embodiment 1, and descriptions thereof are omitted.

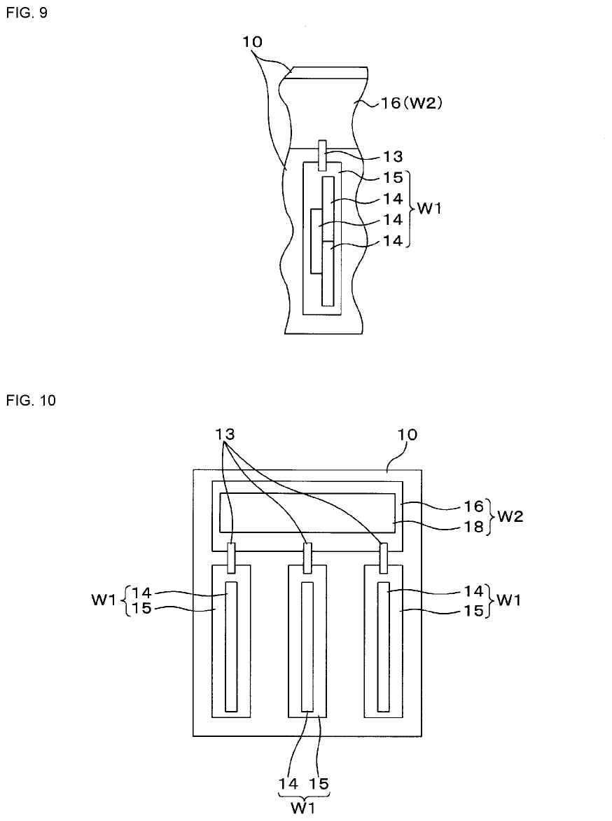

FIG. 10 is a plan view of a circuit device 1 according to Embodiment 5. In the circuit device 1 according to Embodiment 5, a second bus bar 18 is arranged on the second conductive pattern 16. The second conductive pattern 16 is electrically connected to the second bus bar 18. In Embodiment 5, the second conductor W2 is constituted by the second conductive pattern 16 and the second bus bar 18.

Accordingly, when a current flows through the second conductor W2, the current flows not only through the second conductive pattern 16 but also through the second bus bar 18. Therefore, the amount of heat generated in the second conductor W2 when a current flows through the second conductor W2 is also small. In the case where the second bus bar 18 is provided, it is possible to use a conductive pattern that has a small cross section along the perpendicular direction as the second conductive pattern 16.

The same effects as those obtained with use of the circuit device 1 according to Embodiment 1 can be obtained with use of the circuit device 1 according to Embodiment 5.

In the example shown in FIG. 10, the number of first conductive patterns 15 is three. One bus bar 14 is arranged on each first conductive pattern 15. Each first conductor W1 is constituted by the first conductive pattern 15 and the bus bar 14. However, the number of first conductive patterns 15 is not limited to three as described above. The number of bus bars 14 arranged on a common first conductive pattern 15 is not limited to one. When the number of first conductors W1 is two or more, configurations of all the first conductors W1 are not limited to the configuration in which one bus bar 14 is arranged on the first conductive pattern 15.

### Variation of Embodiment 5

The number of second bus bars 18 arranged on the second conductive pattern 16 is not limited to one, and may also be two or more. As the number of second bus bars 18 increases, it is possible to use, as the second conductive pattern 16, a conductive pattern that has a smaller cross section along the perpendicular direction. When a plurality of second bus bars 18 are arranged on the second conductive pattern 16, the shape of a second bus bar 18 may differ from the shape of another second bus bar 18. When a plurality of second bus bars 18 are arranged on the second conductive pattern 16, the second conductor W2 is constituted by the second conductive pattern 16 and the plurality of second bus bars 18. In such a case, the plurality of second bus bars 18 may also be stacked on each other.

### Variations of Embodiments 1 to 5

In each of Embodiments 1 to 5, each bus bar 14 may have a cross section having a shape different from a rectangular shape. In each of Embodiments 1 to 5, when the circuit device 1 includes a plurality of bus bars 14, the shape of a bus bar 14 may differ from the shape of another bus bar 14. In each of Embodiments 2 to 5, when a plurality of bus bars 14 are arranged on a common first conductive pattern 15, the plurality of bus bars 14 may be stacked on each other.

In each of Embodiments 1 to 5, the circuit element connecting each first conductive pattern 15 and the second conductive pattern 16 is not limited to the fuse 13. As a first example of the circuit element, a PTC thermistor may also be used instead of the fuse 13. Similarly to the fuse 13, the PTC thermistor prevents an overcurrent from flowing therethrough. When a current flows through the PTC thermistor, heat is generated in the PTC thermistor. When the temperature of the PTC thermistor increases, the resistance value of the PTC thermistor increases. When the resistance value of the PTC thermistor increases, the current value of a current flowing through the second conductive pattern 16, the circuit element (the PTC thermistor), and the first conductive pattern 15 decreases. Therefore, an overcurrent is prevented from flowing through the second conductive pattern 16 and the first conductive pattern 15. When the fuse 13 is used, a flow of current through the second conductive pattern 16 and the first conductive pattern 15 reliably stops as a result of the thermal cutoff portion of the fuse 13 melting. Therefore, the fuse 13 is preferably used as the element that prevents an overcurrent from flowing therethrough.

As a second example of the circuit element, a circuit element such as a semiconductor switch, a resistor, or an inductor may be used to connect each first conductive pattern 15 and the second conductive pattern 16. As a third example of the circuit element, a series circuit constituted by a semiconductor switch and the fuse 13 may be used to connect each first conductive pattern 15 and the second conductive pattern 16. In the case where a semiconductor switch is used as the circuit element, the semiconductor switch may be switched off when the temperature around the first conductor W1 has reached or exceeded a predetermined threshold temperature. At this time, the semiconductor switch functions as a fuse.

Properties of the circuit element such as a semiconductor switch, a resistor, or an inductor may change depending on the temperature of the circuit element. Even in such a case, the amount of heat generated in the first conductor W1 is small in the circuit devices 1 according to Embodiments 1 to 5. Therefore, the temperature of the circuit element hardly changes due to heat generated in the first conductor W1, and the circuit element functions properly.

Embodiments 1 to 5 disclosed herein are examples in all aspects and should not be construed as limiting the present disclosure. The scope of the present disclosure is defined not by the above description but by the claims, and is intended to encompass all modifications within the meanings and scope that are equivalent to the claims.

1. A circuit device for a vehicle configured to be arranged in a power supply path, the circuit device comprising:
an insulating layer;
a first conductive pattern and a second conductive pattern that are arranged on the insulating layer;
a circuit element connecting the first conductive pattern and the second conductive pattern to each other; and
a bus bar arranged on the first conductive pattern.

2. The circuit device according to claim 1, wherein the circuit element is a fuse.

3. The circuit device according to claim 1,
wherein a current flows through the second conductive pattern, the circuit element, and the first conductive pattern in this order, and
a cross-sectional area of the first conductive pattern taken along a perpendicular direction that is perpendicular to a current direction in which a current flows through the first conductive pattern is smaller than a cross-sectional area of the second conductive pattern taken along the perpendicular direction.

4. The circuit device according to claim 1,
wherein a current flows through the second conductive pattern, the circuit element, and the first conductive pattern in this order, and
an axial direction of the bus bar matches a current direction in which a current flows through the first conductive pattern.

5. The circuit device according to claim 4, comprising:
a plurality of the bus bars,
wherein the plurality of bus bars are lined up along a perpendicular direction that is perpendicular to the current direction.

6. The circuit device according to claim 4, comprising:
a plurality of the bus bars,
wherein the plurality of bus bars are lined up along the current direction.

7. The circuit device according to claim 1, further comprising:
a second bus bar arranged on the second conductive pattern.

8. The circuit device according to claim 1, comprising:
a plurality of the first conductive patterns and a plurality of the circuit elements,
wherein the plurality of circuit elements are connected to the second conductive pattern, and
the plurality of circuit elements are connected to the plurality of first conductive patterns, respectively.
